(19) United States
(12) Patent Application Publication
(10) Pub. No.: US 2005/0048314 A1
(43) Pub. Date: Mar. 3, 2005

(54) Light emitting polymer devices with improved efficiency and lifetime

(76) Inventors: Homer Antoniadis, Mountain View, CA (US); Pierre-Marc Allemand, San Jose, CA (US); Reza Stegamat, Milpitas, CA (US); Vi-En Choong, San Jose, CA (US)

Correspondence Address: Siemens Corporation;Attn: Elsa Keller, Legal Administrator, Intellectual Property Department, 170 Wood Avenue South, Iselin, NJ, 08830, US

(21) Appl. No.: 10/856,594

(22) Filed: May 27, 2004

Related U.S. Application Data
(60) Provisional application No. 60/499,095, filed on Aug. 28, 2003.

(51) Int. Cl. H05B 33/12

(52) U.S. Cl. 428/690; 428/917; 428/212; 428/332; 313/504; 313/506; 427/66

(57) ABSTRACT

In one embodiment of an OLED device, a hole injection/transport layer is added to the device structure in order to increase the number of holes injected into the emissive layer and reduce the number of electrons injected into the added hole injection/transport layer. In a first configuration of the added hole injection/transport layer, the added hole injection/transport layer is comprised of a non-doped hole transporting material that has an IP range between the highest IP value of the adjacent layer on the anode-end and the lowest IP value of the adjacent layer on the “emissive layer”-end. Optionally, in addition, nearly all electron affinities of the added hole injection/transport layer are less than the lowest electron affinity of the adjacent layer on the “emissive layer”-end. In a second configuration of the added hole injection/transport layer, this layer is formed by doping the hole transport material. The dopant is able to abstract electrons from the hole transporting material. By doping the hole transport material, the IP range of the hole transporting material is broadened. In addition or alternatively, the doping produces more HOMO energy states thus allowing more holes to occupy these intermediate states at any one time.

### CROSS-REFERENCE TO RELATED APPLICATIONS

This application claims benefit of U.S. Provisional Patent Application having the Application Number: 60/499,095 filed on Aug. 28, 2003 and entitled “Light Emitting Polymer Devices with Improved Hole Injection Efficiency.”

### BACKGROUND OF THE INVENTION

An organic light emitting diode (“OLED”) device typically includes, for example: (1) an anode on a substrate; (2) a hole transporting layer (“HTL”) on the anode; (3) an electron transporting and light emitting layer (“emissive layer”) on the HTL; and (4) a cathode on the emissive layer. When the device is forward biased, holes are injected from the anode into the HTL, and the electrons are injected from the cathode into the emissive layer. Both carriers are then transported towards the opposite electrode and allowed to recombine with each other in the device, the location of which is called the recombination zone. In this device configuration, the holes have to travel a longer distance to reach the emissive layer compared to the electrons. In addition, there is a large energy barrier for hole injection at the interface between the HTL and the emissive layer that further suppresses the injection of holes into the emissive layer. This often results in the emissive layer being hole deficient and this hole deficiency results in reduced device efficiency. The hole deficiency also results in the recombination of electrons and holes that generate light to be localized in the region of the emissive layer that is very close to the HTL/emissive layer interface and the electrons that fail to recombine in this region leak into the HTL resulting in degradation of this layer and thus decreasing the lifetime of the device.

FIG. 1 shows an energy level diagram for a prior art OLED device. In FIG. 1, the ionization potential (“IP”) is the energy difference between the vacuum level and the highest occupied molecular orbital (“HOMO”) level. The vacuum level is usually referred to as the reference level from which the energy levels are measured. The HOMO is the highest energy level filled with electrons and in which the holes are free to move. Similarly, the lowest unoccupied molecular orbital (“LUMO”) is the lowest energy level devoid of electrons and in which free electrons are free to move. The energy difference between the HOMO level and the LUMO level is the band-gap within which there are no available molecular orbital states. The IP value is a measure of the minimum energy, expressed in electron volts (“eV”), required to remove an electron from an atom. The work function for an anode comprised of indium tin oxide (“ITO”) is typically 4.8 eV. The IP for a HTL comprised of polyethylenedioxythiophene (“PEDOT”) and polystyrenesulfonic acid (“PSS”) (this material is referred to, herein, as PEDOT:PSS) is typically 5.0 eV. The IP for an emissive layer comprised of blue emissive polymer material is typically anywhere from 5.8 eV to 6.0 eV. The work function for a cathode is typically between 2.0 eV and 3.0 eV. The hole injection barrier (“ΔEₕ”) is the difference between the HOMO energy levels of two adjacent layers. In the device configuration described earlier, there is usually a large energy barrier for hole injection at the interface between the HTL and the emissive layer that suppresses the injection of holes into the emissive layer. The energy barrier is considered large if, for example, ΔEₕ is greater than 0.2 eV.

In this device configuration, due in part to the large hole injection barrier, there is typically a larger number of electrons than holes in the emissive layer and some of the “excess” electrons do not recombine in the emissive layer. This imbalance between the number of electrons and holes in the emissive layer results in reduced device efficiency. In addition, the electrons that do not recombine reach the HTL. Because the electron affinity of the blue emissive polymer material is less than the electron affinity of the PEDOT:PSS layer (as used herein, a lower electron affinity means a higher LUMO level), electrons can readily inject from the blue emissive polymer material into the PEDOT:PSS layer because the electrons strive for the lowest possible energy state. The injection of electrons into the HTL can degrade the HTL thus decreasing the device lifetime.

Therefore, in order to improve device efficiency and lifetime, the number of holes reaching the emissive layer should be increased and the number of electrons reaching the HTL should be decreased.

### SUMMARY

An embodiment of an OLED device is described. The OLED device includes a substrate, an anode on the substrate, and a first hole injection/transport layer on the anode. The OLED device further includes a second hole injection/transport layer on the first hole injection/transport layer, an emissive layer on the second hole injection/transport layer, and a cathode on the emissive layer. The second hole injection/transport layer has a range of IPs between a highest IP of an adjacent layer on an anode-end and a lowest IP of an adjacent layer on an “emissive layer”-end.

An embodiment of a method to fabricate an OLED device is also described. The method includes depositing an anode on a substrate, depositing a first hole injection/transport layer on the anode, and depositing a second hole injection/transport layer on the first hole injection/transport layer. The method further includes depositing an emissive layer on the second hole injection/transport layer, and depositing a cathode on the emissive layer. The second hole injection/transport layer has a range of IPs between a highest IP of an adjacent layer on an anode-end and a lowest IP of an adjacent layer on an “emissive layer”-end.

### BRIEF DESCRIPTION OF THE DRAWINGS

FIG. 1 shows an energy level diagram for a prior art OLED device.

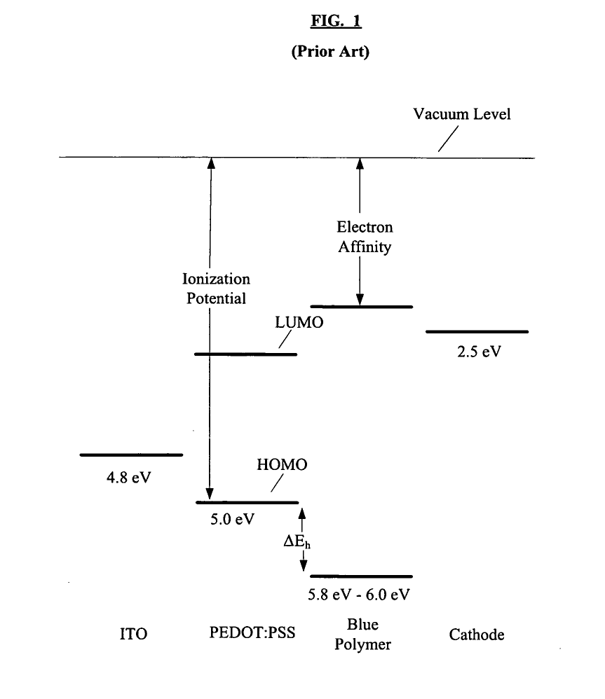

FIG. 2 shows a cross-sectional view of a first embodiment of an OLED device according to the present invention.

FIG. 3 shows an energy level diagram of an example OLED device employing a first configuration of the added hole injection/transport layer.

FIG. 4 shows an energy level diagram of an example OLED device employing a second configuration of the added hole injection/transport layer.

FIG. 5 shows a cross-sectional view of a second embodiment of the OLED device according to the present invention.

### DETAILED DESCRIPTION

As explained earlier, the emissive layer of an OLED device can be hole deficient. In order to improve the device lifetime and efficiency, a hole injection/transport layer is added to the device structure in order to increase the number of holes injected into the emissive layer and reduce the number of electrons injected into the added hole injection/transport layer. If the number of holes injected into the emissive layer is increased, then the efficiency of the device will also increase since the number of holes will be closer to the number of electrons resulting in more recombinations. If there are more recombinations and/or the number of electrons injected into the added hole injection/transport layer is reduced, then fewer electrons eventually reach the HTL and this increases the device lifetime.

In a first configuration of the added hole injection/transport layer, the added hole injection/transport layer is comprised of a non-doped hole transporting material that has an IP range between the highest IP value of the adjacent layer on the anode-end and the lowest IP value of the adjacent layer on the “emissive layer”-end. In other words, the HOMO levels of the added hole injection/transport layer are between the lowest HOMO level of the adjacent layer on the anode-end and the highest HOMO level of the adjacent layer on the “emissive layer”-end.

Optionally, in addition, nearly all of the electron affinities of the added hole injection/transport layer are less than the lowest electron affinity of the adjacent layer on the “emissive layer”-end. In other words, nearly all of the LUMO levels of the added hole injection/transport layer is higher than the highest LUMO level of the adjacent layer on the “emissive layer”-end.

In a second configuration of the added hole injection/transport layer, the added hole injection/transport layer is formed by doping a hole transport material that has an IP range between the highest IP value of the adjacent layer on the anode-end and the lowest IP value of the adjacent layer on the “emissive layer”-end. The dopant is able to abstract electrons from the hole transporting material. By doping the hole transport material, the IP range of the material is broadened so that the resulting doped layer has an IP range that is closer to the highest IP value of the adjacent layer on the anode-end and also closer to the lowest IP value of the adjacent layer on the “emissive layer”-end. In addition or alternatively, the doping produces more HOMO energy states thus allowing more holes to occupy these intermediate states at any one time and this increases the likelihood that more holes are injected into the adjacent layer on the “emissive layer”-end. By doping the hole transporting material, the range of electron affinities of the resulting doped layer is also broadened but nearly all of the electron affinities are less than the lowest electron affinity of the adjacent layer on the “emissive layer”-end.

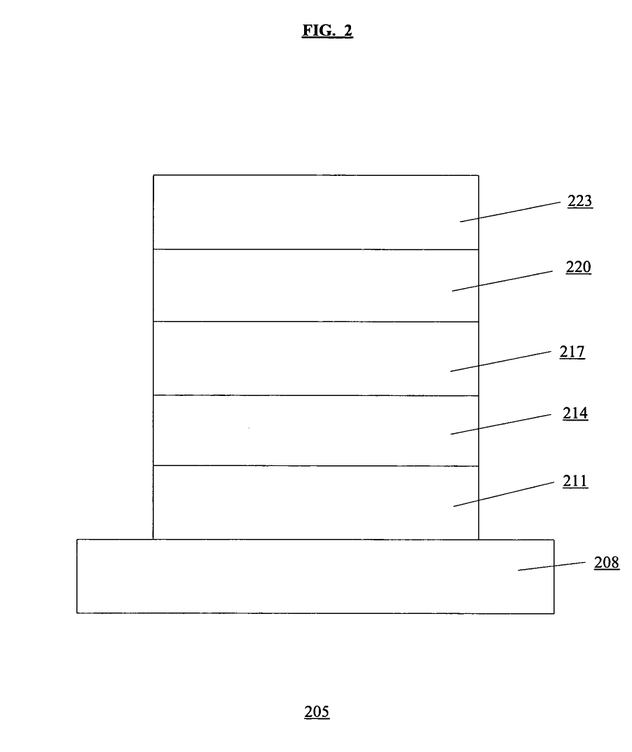

FIG. 2 shows a cross-sectional view of a first embodiment of an OLED device 205 according to the present invention. The OLED device 205 can be, for example, a pixel within an OLED display, or an element within an OLED light source used for general purpose lighting. In FIG. 2, an anode 211 is on a substrate 208. As used within the specification and the claims, the term “on” includes when there is direct physical contact between the two parts and when there is indirect contact between the two parts because they are separated by one or more intervening parts. A first hole injection/transport layer 214 is on the anode 211. A second hole injection/transport layer 217 is on the first hole injection/transport layer 214. An emissive layer 220 is on the second hole injection/transport layer 217. A cathode 223 is on the emissive layer 220. The OLED device 205 may include other layers such as, for example, insulating layers between the anode 211 and the first hole injection/transport layer 214, and/or between the emissive layer 220 and the cathode 223. Some of these layers are described in greater detail below.

Substrate 208

The substrate 208 can be any material, which can support the layers on it. The substrate 208 can be transparent or opaque (e.g., the opaque substrate is used in top-emitting devices). By modifying or filtering the wavelength of light which can pass through the substrate 208, the color of light emitted by the device can be changed. Preferable substrate materials include glass, quartz, silicon, stainless steel, and plastic; preferably, the substrate 208 is comprised of thin, flexible glass. The preferred thickness of the substrate 208 depends on the material used and on the application of the device. The substrate 208 can be in the form of a sheet or continuous film. The continuous film is used, for example, for roll-to-roll manufacturing processes which are particularly suited for plastic, metal, and metallized plastic foils.

Anode 211

The anode 211 is comprised of a high work function material; for example, the anode 211 can have a work function greater than about 4.5 eV. Typical anode materials include metals (such as platinum, gold, palladium, nickel, indium, and the like); metal oxides (such as tin oxide, indium tin oxide (“ITO”), and the like); graphite; doped inorganic semiconductors (such as silicon, germanium, gallium arsenide, and the like); and highly doped conducting polymers (such as polyaniline, polypyrrole, polythiophene, and the like).

The anode 211 can be transparent, semi-transparent, or opaque to the wavelength of light generated within the device. The thickness of the anode 211 is from about 10 nm to about 1000 nm, and preferably, from about 50 nm to about 200 nm.

The anode 211 can typically be fabricated using any of the techniques known in the art for deposition of thin films, including, for example, vacuum evaporation, sputtering, electron beam deposition, or chemical vapor deposition.

First Hole Injection/transport Layer 214

The first hole injection/transport layer 214 has a much higher hole mobility than electron mobility and is used to effectively transport holes from the anode 211. The first hole injection/transport layer 214 is comprised of, for example, PEDOT:PSS, or polyaniline (“PANI”).

The first hole injection/transport layer 214 functions as: (1) a buffer to provide a good bond to the substrate; and/or (2) a hole injection layer to promote hole injection; and /or (3) a hole transport layer to promote hole transport.

The first hole injection/transport layer 214 can be deposited using selective deposition techniques or nonselective deposition techniques. Examples of selective deposition techniques include, for example, ink jet printing, flex printing, and screen printing. Examples of nonselective deposition techniques include, for example, spin coating, dip coating, web coating, and spray coating.

Second Hole Injection/transport Layer 217

In a first configuration of the first embodiment of the present invention, the second hole injection/transport layer 217 is comprised of a non-doped hole transporting material on the first hole injection/transport layer 214. This second hole injection/transport layer 217 has an IP range between the highest IP value of the adjacent layer on the anode-end (e.g., in FIG. 2, this adjacent layer is the first hole injection/transport layer 214) and the lowest IP value of the adjacent layer on the “emissive layer”-end (e.g., in FIG. 2, this adjacent layer is the emissive layer 220). Preferably, the IP range of the first configuration of the second hole injection/transport layer 217 is between: (1) the lowest IP value of the adjacent layer on the “emissive layer”-end, and (2) the midpoint between the lowest IP of the adjacent layer on the “emissive layer”-end and the highest IP of the adjacent layer on the anode-end. The hole transporting material can be any of the materials described below for the second configuration.

Optionally, in addition, nearly all of the electron affinities of the second hole injection/transport layer 217 are less than the lowest electron affinity of the adjacent layer on the “emissive layer”-end.

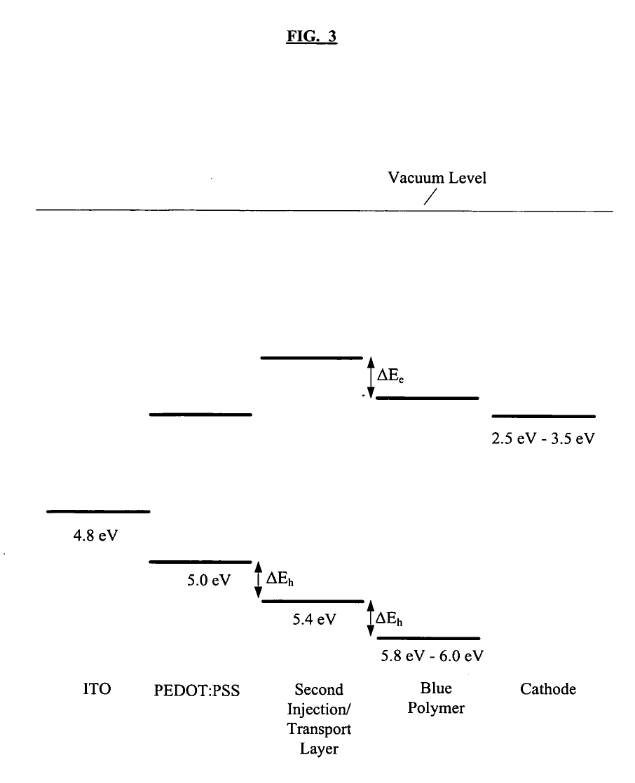

FIG. 3 shows an energy level diagram of an example OLED device employing the first configuration of the second hole injection/transport layer 217. The work function for an anode comprised of indium tin oxide (“ITO”) is typically 4.8 eV. The IP for a HTL comprised of PEDOT:PSS is typically 5.0 eV. The IP of the second injection/transport layer is between the IP of the PEDOT:PSS and the IP of the blue polymer layer. Specifically, in this example, the IP of the second injection/transport layer is 5.4 eV. The IP of the blue polymer layer is between 5.8 eV and 6.0 eV. The cathode typically includes an electron injecting layer that is comprised of, for example, barium, calcium, or a metal fluoride, and also includes a conductive layer comprised of, for example, silver or aluminum. The cathode typically has a work function between 2.5 eV to 3.5 eV. By employing the second injection/transport layer in the device, a greater number of holes can reach the blue polymer layer than if this layer was not present. This is due in part to holes being able to more easily overcome the two smaller energy barriers between (1) the PEDOT:PSS and the second hole injection/transport layer and (2) the second hole injection/transport layer and the blue polymer layer than for holes to overcome the larger energy barrier between the PEDOT:PSS and the blue polymer. Reducing the energy barrier between adjacent layers greatly facilitates hole injection between those layers.

In addition, nearly all of the range of electron affinities of the second injection/transport layer are less than the lowest electron affinity of the blue polymer layer. The electron injection barrier (“ΔEₑ”) from the blue polymer layer to the second injection/transport layer is large enough to substantially reduce the number of electrons that are injected into the second injection/transport layer thus substantially reducing the number of electrons injected into the PEDOT:PSS layer. By reducing the number of electrons that are injected into the PEDOT:PSS layer, the device reliability and/or lifetime can be increased.

In a second configuration of the first embodiment of the present invention, the second hole injection/transport layer 217 is comprised of a hole transporting material that has been doped. Prior to doping, the hole transporting material has an IP range that is between the highest IP value of the adjacent layer on the anode-end (e.g., in FIG. 2, this adjacent layer is the first hole injection/transport layer 214) and the lowest IP value of the adjacent layer on the “emissive layer”-end (e.g., in FIG. 2, this adjacent layer is the emissive layer 220). The hole transporting material, can be, for example, aromatic amines, aromatic hydrazines, or aromatic carbazoles, such as, for example, triphenyldiamine (“TPD”), naphthylphenyldiamine (“NPD”), tetramethylphenylenediamine (“TMPD”), or polymers that include these units as side groups or in the main chain. In addition, the hole transporting material can be conjugated polymers or oligomers with a low ionization potential such as: sexythiophene, polythiophenes, polyphenylenevinylenes (“PPVs”), polyfluorenes, polyfluorenes containing arylamines moieties, or blue polymers (or a close derivative) that is doped with strong electron acceptors so that it serves as a hole transporting material. Also, the hole transporting material can be, for example, an organometallic such as, for example, phthalocyanines.

The hole transporting material is doped with a dopant that is able to abstract electrons from the hole transporting material. The dopant can be any strong electron acceptor or oxidizing agent that is able to abstract electrons from the hole transporting material. These dopants can be, for example: peroxo compounds (e.g., persulfates, perborates, or peroxides); nitrosonium salts (e.g., NO+PF6-); halogens (e.g., chlorine, bromine, or iodine); Lewis acids (e.g., BF3, AlCl3, PCl5, PF5, SbF5, or SbCl5); molecular electron acceptors (e.g., the TCNQ family; the quinones family (e.g., dicyclodicyanobenzoquinone (“DDQ”)); tetracyanoethylene (“TCNE”); and other percyano or nitro compounds (e.g., trinitrofluorenone (“TNF”))). In addition, the IP range of the hole transporting material can be broadened by in-situ electrochemical doping. For example, after fabricating the device, a large forward bias can cause holes to be injected into the second hole injection/transport layer 217 and anions could migrate into the oxidized second hole injection/transport layer 217 to permanently stabilize the holes.

By doping the hole transporting material, the IP range of the resulting doped layer is broader than the IP range of the layer comprised of the undoped hole transporting material. The doping broadens the IP range so that it's closer to both the highest IP value of the adjacent layer on the anode-end and the lowest IP value of the adjacent layer on the “emissive layer”-end. By reducing the energy barrier between states in adjacent layers, there is a greater likelihood that the holes in one layer can more easily overcome the energy barrier and jump to the state having the higher IP value in the adjacent layer. In addition or alternatively, the doping produces more HOMO energy states thus allowing more holes to occupy these intermediate states at any one time and this increases the likelihood that more holes are injected into the adjacent layer on the “emissive layer”-end.

Preferably, the IP range of the second configuration of the second hole injection/transport layer 217 is between: (1) the lowest IP value of the adjacent layer on the “emissive layer”-end, and (2) the midpoint between the lowest IP of the adjacent layer on the “emissive layer”-end and the highest IP of the adjacent layer on the anode-end.

By doping the hole transporting material, the range of electron affinities of the doped material is broadened such that the range is broader than the range of electron affinities of the nondoped material. Even with the broadened range, nearly all of the electron affinities of the doped material is less than the lowest electron affinity of the adjacent layer on the “emissive layer”-end.

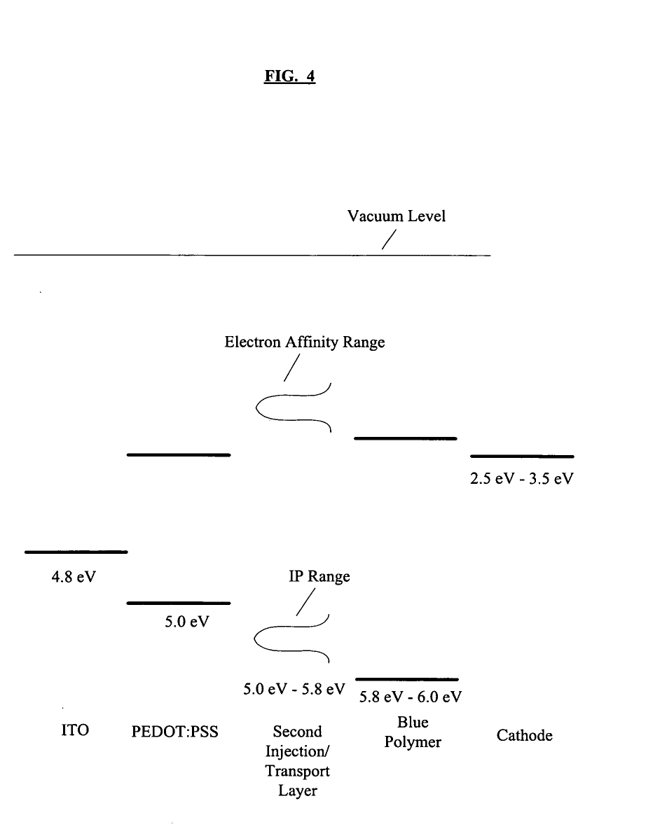

FIG. 4 shows an energy level diagram of an example OLED device employing the second configuration of the second hole injection/transport layer 217. The work function for an anode comprised of indium tin oxide (“ITO”) is typically 4.8 eV. The IP for a HTL comprised of PEDOT:PSS is typically 5.0 eV. The IP range of the second hole injection/transport layer 217 formed from the doped hole transporting material is between 5.0 eV to 5.8 eV. The IP of the blue polymer layer is between 5.8 eV and 6.0 eV. The cathode typically includes an electron injecting layer that is comprised of, for example, barium, calcium, or a metal fluoride, and also includes a conductive layer comprised of, for example, silver or aluminum. The cathode typically has a work function between 2.5 eV to 3.5 eV. By doping the hole transporting material, the IP range of the layer comprised of the doped material is broadened so that its IP range is greater than the IP range of a layer comprised of non-doped hole transporting material. Specifically, by doping the hole transporting material with electron acceptors, the IP of the second injection/transporting layer comprised of the doped material can be increased by, for example, ±0.4 eV so that the IP range of this layer is between 5.0 eV and 5.8 eV. As shown in FIG. 4, the IP values (i.e., energy distribution) may have a Gaussian distribution. By employing the second injection/transport layer comprised of doped hole transporting material, a larger number of holes can be injected into the blue polymer layer (i.e., there's a greater likelihood that holes can overcome the energy barrier and be injected into the blue polymer layer). This is due to the doping that broadens the IP range of the layer so that some of the IP values are brought closer to the IP value of the PEDOT:PSS and some other IP values of the second injection/transport layer are brought closer to the IP values of the blue polymer layer and thus there are HOMO energy states with lower energy barriers that can be more easily overcome therefore increasing the likelihood that a greater number of holes are injected into the blue polymer layer. In addition or alternatively, the doping adds intermediate HOMO energy states that are between the highest IP value of the adjacent layer on the anode-end and the lowest IP value of the adjacent layer on the “emissive layer”-end. The added intermediate states allow a larger number of holes to inject into the blue polymer layer at any one time.

In addition, the second injection/transport layer comprised of the doped hole transporting material has a broader range of electron affinities than the second injection/transport layer comprised of the non-doped hole transporting material. Even with the broader range, nearly all of the electron affinities of the broader range are still less than the lowest electron affinity of the blue polymer. As shown in FIG. 3, the electron affinities of the second hole injection/transport layer may have a Gaussian distribution.

The second hole injection/transport layer 217 functions as: (1) a buffer to provide a good bond to the substrate; and/or (2) a hole injection layer to promote hole injection; and /or (3) a hole transport layer to promote hole transport.

Preferably, the second hole injection/transport layer is thick and has a thickness of between 50 nm and 200 nm.

By including the second hole injection/transport layer 217 within the device 205, the first hole injection/transport layer 214 can be a thick layer or alternatively a thin layer. Specifically, a thick first hole injection/transport layer 217 can have a thickness of, for example, 50 nm to 200 nm. Alternatively, a thin first hole injection/transport layer 217 can have a thickness of, for example, up to 50 nm. One of the many reasons for a thin first hole injection/transport layer 217 is to improve device performance. The first hole injection/transport layer 214 may be comprised of materials such as PEDOT:PSS which contain many impurities and these impurities may contribute to decreased device performance such as, for example, shorter device lifetime. By making the first hole injection/transport layer 214 thin, the amount of impurities that are introduced into the device is decreased. In addition, a thinner first hole injection/transport layer 214 lowers the device resistance thus a lower operating voltage can be used.

The second hole injection/transport layer 217 is formed from a solution having a solvent that won't dissolve the first hole injection/transport layer 214. Preferably, the second hole injection/transport layer 217 is formed using a different solvent than that used to form the first hole injection/transport layer 214. For example, the first hole injection/transport layer 214 is formed from a solution in which an aqueous solvent is used, and the second hole injection/transport layer 217 is formed from a solution in which a non-aqueous solvent (e.g., xylene or toluene) is used. Furthermore, the second hole injection/transport layer 217 should not be dissolved by the solvent used to deposit the emissive polymers to form the emissive layer. Such a property can be achieved by chemically incorporating cross-linkable moieties in the polymer chain of the second hole injection/transport layer 217. Examples of such moieties include double bond, acrylate, and benzocyclobutene (“BCB”).

In a third configuration of the first embodiment of the present invention, the second injection transport layer 217 is comprised of a blend of two or more different types of polymers. The second hole injection/transport layer 217 comprised of the blend of polymers has a range of IPs between a highest IP of an adjacent layer on an anode-end and a lowest IP of an adjacent layer on an “emissive layer”-end; this layer 217 also has a range of electron affinities that is lower than the lowest electron affinity of the adjacent layer on the “emissive layer”-end. Specifically, for example, one type of polymers can be emissive polymers and the other type of polymers can be hole transporting polymers. Examples of hole transporting polymers that can be used in the blend include: (1) aromatic amines, (2) aromatic hydrazines, (3) aromatic carbazoles, (4) conjugated polymers with a low ionization potential, (5) conjugated oligomers with a low ionization potential, (6) organometallics, or (7) TFB. Examples of emissive polymers that can be used in the blend include: polyphenylenevinylene (“PPV”), PPV derivatives and copolymers and blends, polyfluorene (“PF”), PF derivates or copolymers or blends, or super yellow (“SY”).

Alternatively, the different types of polymers in the polymer blend can be those that provide good adhesion with both of the adjacent layers (e.g., in FIG. 2, the adjacent layers are the first hole injection/transport layer 214 and the emissive layer 220). These polymers are compatible with the polymers of the first hole injection/transport layer 214 and wet the surface of this layer well. Examples of such polymers are TFB and PEDOT.

The second hole injection/transport layer 217 can be deposited using selective deposition techniques or nonselective deposition techniques. Examples of selective deposition techniques include, for example, ink jet printing, flex printing, and screen printing. Examples of nonselective deposition techniques include, for example, spin coating, dip coating, web coating, and spray coating.

Emissive Layer 220

The emissive layer 220 is comprised of an organic electroluminescent material. The organic electroluminescent material can be comprised of organic polymers or organic small molecules. Preferably, the organic polymers are fully or partially conjugated polymers. For example, suitable organic polymer materials include one or more of the following in any combination: poly(p-phenylenevinylene) (“PPV”), poly(2-methoxy-5(2′-ethyl)hexyloxyphenylenevinylene) (“MEH-PPV”), one or more PPV-derivatives (e.g. di-alkoxy or di-alkyl derivatives), polyfluorenes and/or co-polymers incorporating polyfluorene segments, PPVs and related co-polymers, poly(2,7-(9,9-di-n-octylfluorene)-(1,4-phenylene-((4-secbutylphenyl)imino)-1,4-phenylene)(“TFB”), poly(2,7-(9,9-di-n-octylfluorene)-(1,4-phenylene-((4-methylphenyl)imino)-1,4-phenylene-((4-methylphenyl)imino)-1,4-phenylene))(“PFM”), poly(2,7-(9,9-di-n-octylfluorene)-(1,4-phenylene-((4-methoxyphenyl)imino)-1,4-phenylene))(“PFMO”), poly(2,7-(9,9-di-n-octylfluorene) (“F8”), (2,7-(9,9-di-n-octylfluorene)-3,6-Benzothiadiazole)(“F8BT”), or poly(9,9-dioctylfluorene).

A preferred organic electroluminescent material that emits blue light is LUMATION LEPs that emit blue light available from Dow Chemical, Midland, Mich. (a polyfluorene based polymer); another electroluminescent material is polyspirofluorene like polymers available from Covion Organic Semiconductors GmbH, Frankfurt, Germany. Other blue emitting polymer are, for example, poly(9,9-dialkyl fluorene), poly(9,9-diaryl fluorene), polyphenylenes, poly(2,5-dialkyl phenylene), copolymers of these materials, or copolymers with monomers comprising arylamine units.

An organic electroluminescent material that emits yellow light and includes polyphenelenevinylene derivatives is available from Covion Organic Semiconductors GmbH, Industrial park Hoechst, Frankfurt, Germany. Yet other organic electroluminescent materials that emit red, green or white light and includes fluorene-copolymers are available from the LUMATION LEP series from Dow Chemical, Midland, Mich.

Alternatively, rather than polymers, small organic molecules that emit by fluorescence or by phosphorescence can serve as the organic electroluminescent layer. Examples of small-molecule organic electroluminescent materials include: (i) tris(8-hydroxyquinolinato)aluminum(Alq); (ii) 1,3-bis(N,N-dimethylaminophenyl)-1,3,4-oxidazole(OXD-8); (iii)-oxo-bis(2-methyl-8-quinolinato)aluminum; (iv) bis(2-methyl-8-hydroxyquinolinato)aluminum; (v) bis(hydroxybenzoquinolinato)beryllium(BeQ.sub.2); (vi) bis(diphenylvinyl)biphenylene (DPVBI); and (vii) arylamine-substituted distyrylarylene (DSA amine).

Such polymer and small-molecule materials are well known in the art and are described in, for example: (1) U.S. Pat. No. 5,047,687 issued to VanSlyke, and (2) Bredas, J. -L., Silbey, R., eds., Conjugated Polymers, Kluwer Academic Press, Dordrecht (1991).

As indicated earlier, the emissive layer 220 is comprised of, for example, conjugated polymers or nonconjugated polymers. The emissive layer 220 is formed from a solvent that won't dissolve the second hole injection/transport layer 217. Preferably, the emissive layer 220 is formed from a different solvent than that used to form the second hole injection/transport layer 217.

The thickness of the emissive layer 220 is from about 5 nm to about 500 nm, and preferably, from about 20 nm to about 100 nm.

The emissive layer 220 can be deposited using selective deposition techniques or nonselective deposition techniques. Examples of selective deposition techniques include, for example, ink jet printing, flex printing, and screen printing. Examples of nonselective deposition techniques include, for example, spin coating, dip coating, web coating, and spray coating.

Cathode 223

The cathode 223 is a conductive layer which serves as an electron-injecting layer and which comprises a material with a low work function. The cathode is typically a multilayer structure that includes, for example, a thin charge injection layer and a thick conductive layer. The charge injection layer has a lower work function than the conductive layer. The charge injection layer can be comprised of, for example, calcium or barium or mixtures thereof. The conductive layer can be comprised of, for example, aluminum, silver, magnesium, or mixtures thereof. Alternatively, the cathode can be a three layer structure where, for example, the charge injection layer is on a layer of lithium fluoride.

The cathode 223 can be opaque, transparent, or semi-transparent to the wavelength of light generated within the device. The thickness of the cathode 223 is from about 10 nm to about 1000 nm, preferably from about 50 nm to about 500 nm, and more preferably, from about 100 nm to about 300 nm.

The cathode 223 can typically be fabricated using any of the techniques known in the art for deposition of thin films, including, for example, vacuum evaporation, sputtering, electron beam deposition, or chemical vapor deposition.

Alternatively, in another embodiment of the OLED device, the cathode layer, rather than the anode layer, is deposited on the substrate. In this case, the emissive polymer layer is deposited on the cathode layer, and the second hole injection/transport layer is deposited on the emissive polymer layer. The first hole injection/transport layer is deposited on the second hole injection/transport layer, and the anode is deposited on the first hole injection/transport layer. This resulting device represents, for example, a top-emitting OLED device.

By adding the second hole injection/transport layer 217 to the OLED device structure, the injection of holes from the first hole injection/transport layer 214 to the emissive layer 220 is more efficient, thus a lower operating voltage can be used to drive the device resulting in greater power efficiency and longer device lifetime.

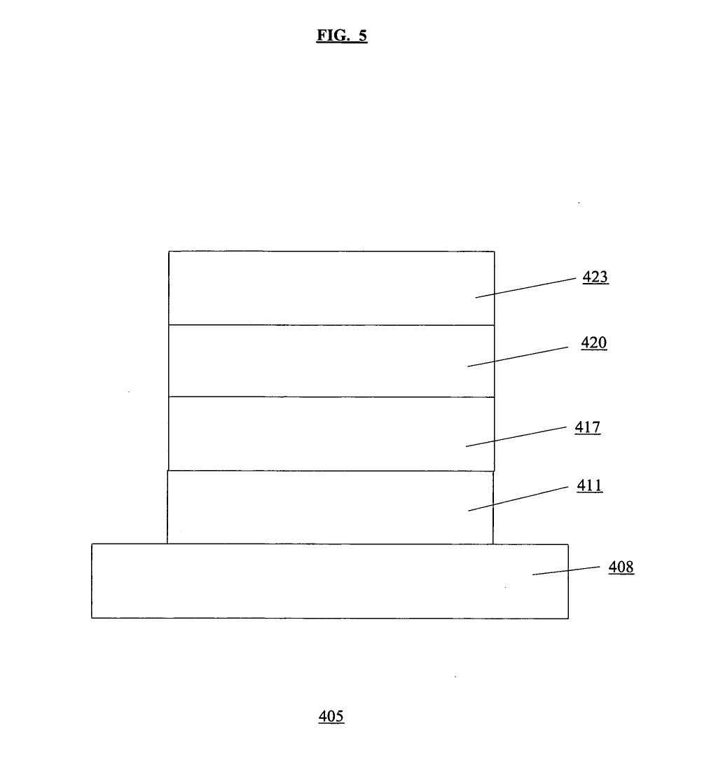

The first hole injection/transport layer may be comprised of materials such as PEDOT:PSS which contain many impurities. These impurities can contribute to decreased device performance such as, for example, shorter device lifetime. Also, the first hole injection/transport layer is a semiconductive material that increases the resistance of the device thus increasing the voltage needed to drive the device. Typically, as the operating voltage is increased, the device lifetime decreases. Therefore, in order to improve device performance and decrease the operating voltage, the first hole injection/transport layer can be eliminated. FIG. 5 shows a cross-sectional view of a second embodiment of an OLED device 405 according to the present invention. In this embodiment, by including the second hole injection/transport layer within the device, the first hole injection/transport layer can be eliminated. In FIG. 5, an anode 411 is on a substrate 408. An injection/transport layer 417 is on the anode 411. An emissive layer 420 is on the injection/transport layer 417. A cathode 423 is on the emissive layer 420.

In a first configuration of the second embodiment of the present invention, the injection/transport layer 417 is comprised of nondoped hole transporting material. The injection/transport layer 417 has an IP range between the highest IP value of the adjacent layer on the anode-end (e.g., in FIG. 5, this adjacent layer is the anode 411) and the lowest IP value of the adjacent layer on the “emissive layer”-end (e.g., in FIG. 5, this adjacent layer is the emissive layer 420). Optionally, in addition, nearly all of the electron affinities of the injection/transport layer 417 is lower than the lowest electron affinity of the adjacent layer on the “emissive layer”-end (e.g., the emissive layer 420). The hole transporting material, can be any of the materials described earlier.

In a second configuration of this embodiment of the device, the injection/transport layer 417 is comprised of a hole transporting material that has been doped. Prior to doping, the hole transporting material has an IP range that is between the highest IP value of the adjacent layer on the anode-end and the lowest IP value of the adjacent layer on the “emissive layer”-end. By doping the hole transporting material, the IP range of the resulting doped layer is broader than the IP range of the layer comprised of the undoped hole transporting material. In addition or alternatively, the doping produces more HOMO energy states thus allowing more holes to occupy these intermediate states at any one time and this increases the likelihood that more holes are injected into the adjacent layer on the “emissive layer”-end. Doping the hole transporting material results in the broadening of the electron affinities of the doped material such that the range is broader than the range of electron affinities of the nondoped material; however, nearly all of the electron affinities of the doped material is lower than the lowest electron affinity of the adjacent layer on the “emissive layer”-end.

Preferably, the injection/transport layer 417 is thick and has a thickness of between 50 nm and 200 nm.

The OLED devices described earlier can be used within displays in applications such as, for example, computer displays, information displays in vehicles, television monitors, telephones, printers, and illuminated signs. Alternatively, the OLED devices can be used within an OLED light source for general purpose lighting.

As any person of ordinary skill in the art of electronic device fabrication will recognize from the description, figures, and examples that modifications and changes can be made to the embodiments of the invention without departing from the scope of the invention defined by the following claims.

1. An OLED device, comprising:
a substrate;
an anode on said substrate;
a first hole injection/transport layer on said anode;
a second hole injection/transport layer on said first hole injection/transport layer;
an emissive layer on said second hole injection/transport layer; and
a cathode on said emissive layer,
wherein said second hole injection/transport layer has a range of ionization potentials (“IPs”) between a highest IP of an adjacent layer on an anode-end and a lowest IP of an adjacent layer on an “emissive layer”-end.

2. The OLED device of claim 1 wherein nearly all electron affinities of said second hole injection/transport layer are less than the lowest electron affinity of said adjacent layer on said “emissive layer”-end.

3. The OLED device of claim 1 wherein
said adjacent layer on said anode-end is said first hole injection/transport layer, and
said adjacent layer on said “emissive layer”-end is said emissive layer.

4. The OLED device of claim 2 wherein said second hole injection/transport layer increases the likelihood that holes are injected into the emissive layer, and said second hole injection/transport layer decreases the likelihood that electrons are injected into the first hole injection/transport layer.

5. The OLED device of claim 1 wherein
said second hole injection/transport layer is comprised of a hole transport material, wherein said hole transport material is any one of: (1) aromatic amines, (2) aromatic hydrazines, (3) aromatic carbazoles, (4) conjugated polymers with a low ionization potential, (5) conjugated oligomers with a low ionization potential, or (6) organometallics.

6. The OLED device of claim 1 wherein
said second hole injection/transport layer is comprised of a hole transport material that is doped with a dopant that is able to abstract electrons from said hole transport material.

7. The OLED device of claim 6 wherein
said hole transport material is any one of: (1) aromatic amines, (2) aromatic hydrazines, (3) aromatic carbazoles, (4) conjugated polymers with a low ionization potential, (5) conjugated oligomers with a low ionization potential, or (6) organometallics, and
said dopant is any one of: peroxo compounds, nitrosonium salts, halogens, Lewis acids, or molecular electron acceptors.

8. The OLED device of claim 6 wherein
doping said second hole injection/transport layer broadens said range of IPs such that some of said IPs of said second hole injection/transport layer are brought closer to said highest IP of said adjacent layer on said anode-end, and some of said IPs of said second hole injection/transport layer are brought closer to said lowest IP of said adjacent layer on said “emissive layer”-end.

9. The OLED device of claim 6 wherein
doping said second hole injection/transport layer adds additional HOMO energy states to said layer that have IPs between said highest IP of said adjacent layer on said anode-end and said lowest IP of said adjacent layer on said “emissive layer”-end.

10. The OLED device of claim 1 wherein
a thickness of said first hole injection/transport layer is up to 50 nm; and
a thickness of said second hole injection/transport layer is from 50 nm to 200 nm.

11. The OLED device of claim 1 wherein
said second hole injection/transport layer is formed from a first solution having a first solvent that is different than a second solvent of a second solution used to form said first hole injection/transport layer.

12. The OLED device of claim 1 wherein
said second hole injection/transport layer is comprised of polymers with crosslinked moieties that prevent a solvent of a solution used to form said emissive layer from dissolving said second hole injection/transport layer.

13. The OLED device of claim 1 wherein
said second hole injection/transport layer is comprised of a blend of a plurality of different types of polymers.

14. The OLED device of claim 13 wherein
said blend of said plurality of different types of polymers provides good adhesion with both said adjacent layer on said anode-end and said adjacent layer on said “emissive layer”-end.

15. The OLED device of claim 1 wherein said OLED device is a pixel of an OLED display or said OLED device is an element of an OLED light source used for general purpose lighting.

16. A method to fabricate an OLED device, comprising:
depositing an anode on a substrate;
depositing a first hole injection/transport layer on said anode;
depositing a second hole injection/transport layer on said first hole injection/transport layer;
depositing an emissive layer on said second hole injection/transport layer; and
depositing a cathode on said emissive layer,
wherein said second hole injection/transport layer has a range of IPs between a highest IP of an adjacent layer on an anode-end and a lowest IP of an adjacent layer on an “emissive layer”-end.

17. The method of claim 16 wherein nearly all electron affinities of said second hole injection/transport layer are less than the lowest electron affinity of said adjacent layer on said “emissive layer”-end.

18. The method of claim 16 wherein said second hole injection/transport layer is comprised of a hole transport material, wherein said hole transport material is any one of: (1) aromatic amines, (2) aromatic hydrazines, (3) aromatic carbazoles, (4) conjugated polymers with a low ionization potential, (5) conjugated oligomers with a low ionization potential, or (6) organometallics.

19. The method of claim 16 wherein said second hole injection/transport layer is comprised of a hole transport material, and wherein depositing said second hole injection/transport layer includes
doping said hole transport material with a dopant that is able to abstract electrons from said hole transport material, and
depositing said doped hole transport material on said first hole injection/transport layer; and
allowing said deposited material to dry to form said second hole injection/transport layer.

20. The method of claim 19 wherein doping said hole transport material broadens said range of IPs so that some of the IPs are closer to said highest IP of said adjacent layer on said anode-end and some other IPs are closer to said lowest IP of said adjacent layer on said “emissive layer”-end.

21. The method of claim 19 wherein doping said hole transport material adds additional HOMO energy states to said second hole injection/transport layer that are between said highest IP of said adjacent layer on said anode-end and said lowest IP of said adjacent layer on said “emissive layer”-end.

22. The method of claim 19 wherein
said hole transport material is any one of: (1) aromatic amines, (2) aromatic hydrazines, (3) aromatic carbazoles, (4) conjugated polymers with a low ionization potential, (5) conjugated oligomers with a low ionization potential, or (6) organometallics, and
said dopant is any one of: peroxo compounds, nitrosonium salts, halogens, Lewis acids, or molecular electron acceptors.

23. The method of claim 16 wherein
said second hole injection/transport layer is comprised of a blend of a plurality of different types of polymers.

24. An OLED device, comprising:
a substrate;
an anode on said substrate;
a hole injection/transport layer on said anode;
an emissive layer on said hole injection/transport layer; and
a cathode on said emissive layer,
wherein said hole injection/transport layer is comprised of a hole transport material that is doped with a dopant that is able to abstract electrons from said hole transport material, and said hole injection/transport layer has a range of IPs between a highest IP of an adjacent layer on an anode-end and a lowest IP of an adjacent layer on an “emissive layer”-end, and nearly all electron affinities of said hole injection/transport layer are less than the lowest electron affinity of said adjacent layer on said “emissive layer”-end.

25. The OLED device of claim 24 wherein
said hole transport material is any one of: (1) aromatic amines, (2) aromatic hydrazines, (3) aromatic carbazoles, (4) conjugated polymers with a low ionization potential, (5) conjugated oligomers with a low ionization potential, or (6) organometallics, and
said dopant is any one of: peroxo compounds, nitrosonium salts, halogens, Lewis acids, or molecular electron acceptors.

26. The OLED device of claim 24 further comprising another hole injection/transport layer between said anode and said hole injection/transport layer, wherein said other hole injection/transport layer has an IP between an IP of said anode and a lowest IP of said hole injection/transport layer.

27. The OLED device of claim 24 wherein said OLED device is a pixel of an OLED display or said OLED device is an element of an OLED light source used for general purpose lighting.

28. An OLED device, comprising:
a substrate;
a cathode on said substrate;
an emissive layer on said cathode;
a first hole injection/transport layer on said emissive layer;
a second hole injection/transport layer on said first hole injection/transport layer; and
an anode on said second hole injection/transport layer,
wherein said first hole injection/transport layer has a range of IPs between a highest IP of an adjacent layer on an anode-end and a lowest IP of an adjacent layer on an “emissive layer”-end.

29. The OLED device of claim 28 wherein nearly all electron affinities of said first hole injection/transport layer are less than the lowest electron affinity of said adjacent layer on said “emissive layer”-end.

30. The OLED device of claim 28 wherein
said first hole injection/transport layer is comprised of a hole transport material, wherein said hole transport material is any one of: (1) aromatic amines, (2) aromatic hydrazines, (3) aromatic carbazoles, (4) conjugated polymers with a low ionization potential, (5) conjugated oligomers with a low ionization potential, or (6) organometallics.

31. The OLED device of claim 28 wherein
said first hole injection/transport layer is comprised of a hole transport material that is doped with a dopant that is able to abstract electrons from said hole transport material.

32. The OLED device of claim 28 wherein
said hole transport material is any one of: (1) aromatic amines, (2) aromatic hydrazines, (3) aromatic carbazoles, (4) conjugated polymers with a low ionization potential, (5) conjugated oligomers with a low ionization potential, or (6) organometallics, and
said dopant is any one of: peroxo compounds, nitrosonium salts, halogens, Lewis acids, or molecular electron acceptors.
